(19) United States
(12) Patent Application Publication
(10) Pub. No.: US 2022/0328338 A1
(43) Pub. Date: Oct. 13, 2022

(54) SMALL MOLECULE FILMS FOR SACRIFICIAL BRACING, SURFACE PROTECTION, AND QUEUE-TIME MANAGEMENT

(71) Applicants: Lam Research Corporation, Fremont, CA (US); The Regents of the University of California, Oakland, CA (US)

(72) Inventors: Gregory BLACHUT, Campbell, CA (US); Diane HYMES, San Jose, CA (US); Stephen M. SIRARD, Austin, TX (US); Ratchana LIMARY, Austin, TX (US); Christopher M. Bates, Santa Barbara, CA (US)

(21) Appl. No.: 17/639,869

(22) PCT Filed: Sep. 1, 2020
(86) PCT No.: PCT/US2020/048955

§ 371 Date: Mar. 2, 2022

Related U.S. Application Data
(60) Provisional application No. 62/895,921, filed on Sep. 4, 2019.

(51) Int. Cl. H01L 21/683

(52) U.S. Cl. CPC H01L 21/6835; H01L 2221/6834; H01L 2221/68381

(57) ABSTRACT

The present disclosure relates to methods of forming a film including small molecules. Such methods can optionally include removing such small molecules, such as by way of sublimation, evaporation, or conversion to a more volatile form.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### FIELD

The present disclosure relates to methods of forming a film including small molecules. Such methods can optionally include converting the small molecules to a less volatile form and/or removing such small molecules, such as by way of sublimation, evaporation, or conversion to a more volatile form.

### BACKGROUND

During semiconductor fabrication, many surfaces are sensitive to airborne molecular contaminants (AMCs) in the surrounding environment. Queue time can lead to exposure to the AMCs and unwanted interactions such as oxidation, corrosion, and halogenation. Solutions include storing partially fabricated semiconductor substrates in nitrogen (N₂)-filled storage cassettes or rooms and using integrated tools that support multiple processes without breaking the vacuum on the substrates. These solutions are difficult and expensive to implement and pose safety and reliability concerns.

Furthermore, as semiconductor devices continue to scale down to smaller sizes, higher aspect ratio structures are used to achieve the desired device performance. The fabrication of semiconductor devices involves multiple iterations of processes such as material deposition, planarization, feature patterning, feature etching, and feature cleaning. The drive towards higher aspect ratio structures creates processing challenges for many of these traditional fabrication steps. Wet processes such as etch and clean, which may make up greater than 25% of the overall process flow, are particularly challenging on high aspect ratio (HAR) features due to the capillary forces that are generated during drying. The strength of these capillary forces depends on the surface tension and contact angle of the etch, clean, or rinse fluids that are being dried, as well as the feature spacing and aspect ratio. If the forces generated during drying are too high, then the high aspect ratio features will collapse onto each other and stiction may occur. Feature collapse and stiction will severely degrade the device yield.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect of the disclosure encompasses a method including: forming a film including small molecules on the surface of a substrate to protect the surface, thereby providing a protected surface. In some embodiments, said forming a film includes a vapor having the small molecules or a solution having the small molecules. In other embodiments, the method further includes: storing the protected surface in ambient conditions; and removing the small molecules from the surface of the substrate.

In particular embodiments, said removing the small molecules includes inducing sublimation or evaporation of the small molecules. In other embodiments, said removing can include applying a stimulus (e.g., any described herein). In yet other embodiments, the method further includes (e.g., prior to said removing the small molecules) converting the small molecules to a more volatile form.

In some embodiments, the method further includes converting the small molecules on the surface of the substrate to a less volatile form (e.g., prior to said storing the protected surface in ambient conditions). In particular embodiments, said converting the small molecules to a less volatile form includes photoisomerization, photodimerization, photopolymerization, or a Diels-Alder reaction.

Another aspect of the disclosure encompasses a method including: forming a film having small molecules on a surface including high aspect ratio (HAR) structures, wherein the film can fill the HAR structures or form within the HAR structures; and exposing the substrate to a stimulus to induce sublimation of the small molecules. In some embodiments, said forming a film includes a vapor having the small molecules or a solution having the small molecules.

In other embodiments, the substrate including HAR structures further includes a first solvent. In yet other embodiments, the method further includes: displacing the first solvent with a solution including small molecules; and drying the substrate to form a solid film of small molecules.

In some embodiments, the small molecules are characterized by having a vapor pressure of less than about 76 mTorr at room temperature. In other embodiments, the small molecules are solid at room temperature and atmospheric pressure. In yet other embodiments, the small molecules have a vapor pressure of at least 10 Torr and no melting point at temperature less than about 400° C.

In any embodiment herein, the small molecules are fused aromatic rings.

In any embodiment herein, the small molecules are anthracene or naphthalene.

In any embodiment herein, at least one of the small molecules includes a compound including one of formulas (I), (II), (III), (IV), (V), (VI), (VIa), (VIb), (VII), (VIIa), (VIIb), (VIIc), and (VIId), as described herein.

In any embodiment herein, the small molecules are converted to a compound including one of formulas (Ia), (IIa), (IIIa), (IVa), (Va), (VIII), (VIIIa), (VIIIb), (VIIIc), (VIIId), or (VIIIe), as described herein.

In any embodiment herein, the film is formed in a process chamber in which the substrate was immediately previously processed.

### Definitions

The term “acyl,” or “alkanoyl,” as used interchangeably herein, represents an alkyl group, as defined herein, or hydrogen attached to the parent molecular group through a carbonyl group, as defined herein. This group is exemplified by formyl, acetyl, propionyl, butanoyl, and the like. The alkanoyl group can be substituted or unsubstituted. For example, the alkanoyl group can be substituted with one or more substitution groups, as described herein for alkyl. In some embodiments, the unsubstituted acyl group is a C₂₋₇ acyl or alkanoyl group. In particular embodiments, the alkanoyl group is —C(O)-Ak, in which Ak is an alkyl group, as defined herein.

By “acyloxy” or “alkanoyloxy,” as used interchangeably herein, is meant an acyl or alkanoyl group, as defined herein, attached to the parent molecular group through an oxy group. In particular embodiments, the alkanoyloxy is —O—C(O)-Ak, in which Ak is an alkyl group, as defined herein. In some embodiments, an unsubstituted alkanoyloxy is a C₂₋₇ alkanoyloxy group. Exemplary alkanoyloxy groups include acetoxy.

By “aldehyde” is meant H—C(O)—R, in which R is an organic moiety (e.g., optionally substituted alkyl or optionally substituted aryl, as described herein).

By “alkenyl” is meant an optionally substituted C₂₋₂₄ alkyl group having one or more double bonds. The alkenyl group can be cyclic (e.g., C₃₋₂₄ cycloalkenyl) or acyclic. The alkenyl group can also be substituted or unsubstituted. For example, the alkenyl group can be substituted with one or more substitution groups, as described herein for alkyl.

By “alkene” is meant an organic moiety having one or more double bonds. In one instance, an alkene is X—R, in which R is optionally substituted alkenyl, as described herein, and X is H, halo, alkyl, alkoxy, or hydroxyl.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkoxycarbonyl” is meant an alkoxy group, as defined herein, that is attached to the parent molecular group through a carbonyl group. In particular embodiments, the alkoxycarbonyl group is —C(O)—OAk, in which Ak is an alkyl group, as defined herein. In some embodiments, an unsubstituted alkoxycarbonyl group is a C₂₋₇ alkoxycarbonyl group.

By “alkyl” and the prefix “alk” is meant a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃₋₂₄ cycloalkyl) or acyclic. The alkyl group can be branched or unbranched. The alkyl group can also be substituted or unsubstituted. For example, the alkyl group can be substituted with one, two, three or, in the case of alkyl groups of two carbons or more, four substituents independently selected from the group consisting of: (1) C₁₋₆ alkoxy (e.g., —O-Ak, wherein Ak is optionally substituted C₁₋₆ alkyl); (2) C₁₋₆ alkylsulfinyl (e.g., —S(O)-Ak, wherein Ak is optionally substituted C₁₋₆ alkyl); (3) C₁₋₆ alkylsulfonyl (e.g., —SO₂-Ak, wherein Ak is optionally substituted C₁₋₆ alkyl); (4) amino (e.g., —NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (5) aryl; (6) arylalkoxy (e.g., —O-L-Ar, wherein L is a bivalent form of optionally substituted alkyl and Ar is optionally substituted aryl); (7) aryloyl (e.g., —C(O)—Ar, wherein Ar is optionally substituted aryl); (8) azido (e.g., —N₃); (9) cyano (e.g., —CN); (10) carboxyaldehyde (e.g., —C(O)H); (11) C₃₋₈ cycloalkyl (e.g., a monovalent saturated or unsaturated non-aromatic cyclic C₃₋₈ hydrocarbon group); (12) halo (e.g., F, Cl, Br, or I); (13) heterocyclyl (e.g., a 5-, 6- or 7-membered ring, unless otherwise specified, containing one, two, three, or four non-carbon heteroatoms, such as nitrogen, oxygen, phosphorous, sulfur, or halo); (14) heterocyclyloxy (e.g., —O-Het, wherein Het is heterocyclyl, as described herein); (15) heterocyclyloyl (e.g., —C(O)—Het, wherein Het is heterocyclyl, as described herein); (16) hydroxyl (e.g., —OH); (17) N-protected amino; (18) nitro (e.g., —NO₂); (19) oxo (e.g., ═O); (20) C₃₋₈ spirocyclyl (e.g., an alkylene or heteroalkylene diradical, both ends of which are bonded to the same carbon atom of the parent group); (21) C₁₋₆ thioalkoxy (e.g., —S-Ak, wherein Ak is optionally substituted C₁₋₆ alkyl); (22) thiol (e.g., —SH); (23) —CO₂R^{A}, where R^{A} is selected from the group consisting of (a) hydrogen, (b) C₁₋₆ alkyl, (c) C₄₋₁₈ aryl, and (d) (C₄₋₁₈ aryl) C₁₋₆ alkyl (e.g., -L-Ar, wherein L is a bivalent form of optionally substituted alkyl group and Ar is optionally substituted aryl); (24) —C(O)NR^{B}R^{C}, where each of R^{B} and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -L-Ar, wherein L is a bivalent form of optionally substituted alkyl group and Ar is optionally substituted aryl); (25) —SO₂R^{D}, where R^{D} is selected from the group consisting of (a) C₁₋₆ alkyl, (b) C₄₋₁₈ aryl, and (c) (C₄₋₁₈ aryl) C₁₋₆ alkyl (e.g., -L-Ar, wherein L is a bivalent form of optionally substituted alkyl group and Ar is optionally substituted aryl); (26) —SO₂NR^{E}R^{F}, where each of R^{E} and R^{F} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -L-Ar, wherein L is a bivalent form of optionally substituted alkyl group and Ar is optionally substituted aryl); and (27) —NR^{G}R^{H}, where each of R^{G} and R^{H} is, independently, selected from the group consisting of (a) hydrogen, (b) an N-protecting group, (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., L-Ar, wherein L is a bivalent form of optionally substituted alkyl group and Ar is optionally substituted aryl), (h) C₃₋₈ cycloalkyl, and (i) (C₃₋₈ cycloalkyl) C₁₋₆ alkyl (e.g., -L-Cy, wherein L is a bivalent form of optionally substituted alkyl group and Cy is optionally substituted cycloalkyl, as described herein), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene” is meant a multivalent (e.g., bivalent) form of an alkyl group, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. The alkylene group can be branched or unbranched. The alkylene group can also be substituted or unsubstituted. For example, the alkylene group can be substituted with one or more substitution groups, as described herein for alkyl.

By “alkynyl” is meant an optionally substituted C₂₋₂₄ alkyl group having one or more triple bonds. The alkynyl group can be cyclic or acyclic and is exemplified by ethynyl, 1-propynyl, and the like. The alkynyl group can also be substituted or unsubstituted. For example, the alkynyl group can be substituted with one or more substitution groups, as described herein for alkyl.

By “alkyne” is meant an organic moiety having one or more triple bonds. In one instance, an alkyne is X—R, in which R is optionally substituted alkynyl, as described herein, and X is H, halo, alkyl, alkoxy, or hydroxyl.

By “amino” is meant —NR^{N1}R^{N2}, where each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein.

By “aminoalkyl” is meant an alkyl group, as defined herein, substituted by an amino group, as defined herein.

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes “heteroaryl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents described herein, e.g., for alkyl.

By “aryloxy” is meant —OR, where R is an optionally substituted aryl group, as described herein. In some embodiments, an unsubstituted aryloxy group is a C₄₋₁₈ or C₆₋₁₈ aryloxy group.

By “aryloxycarbonyl” is meant an aryloxy group, as defined herein, that is attached to the parent molecular group through a carbonyl group. In some embodiments, an unsubstituted aryloxycarbonyl group is a C₅₋₁₉ aryloxycarbonyl group. In particular embodiments, the aryloxycarbonyl group is —C(O)—OAr, in which Ar is an aryl group, as defined herein.

By “aryloyl” is meant an aryl group that is attached to the parent molecular group through a carbonyl group. In some embodiments, an unsubstituted aryloyl group is a C₂₋₁₁ aryloyl or C₅₋₁₉ aryloyl group. In particular embodiments, the aryloyl group is —C(O)—Ar, in which Ar is an aryl group, as defined herein.

By “aryloyloxy” is meant an aryloyl group that is attached to the parent molecular group through an oxy group. In some embodiments, an unsubstituted aryloyloxy group is a C₇₋₁₁ aryloyloxy or C₅₋₁₉ aryloyloxy group. In particular embodiments, the aryloyloxy group is —OC(O)-Ar, in which Ar is an aryl group, as defined herein.

By “azido” is meant an —N₃ group.

By “azidoalkyl” is meant an azido group attached to the parent molecular group through an alkyl group, as defined herein.

By “carbocycle” is meant a compound having one or more carbon-containing cyclic moieties. Non-limiting carbocycles include benzene, naphthalene, anthracene, phenanthrene, cyclohexadiene, cyclohexene, cyclohexane, indane, acenaphthene, aceanthrene, acephenanthrene, cholanthrene, dihydronaphthalene, tetralin, and decalin. Optional substitutions for carbocycles include any described herein for alkyl. Carbocycles can also include cations and/or salts of any of these.

By “carboxyaldehyde” is meant a —C(O)H group.

By “carboxyalkyl” is meant an alkyl group, as defined herein, substituted by a carboxyl group, as defined herein.

By “carboxyl” is meant a —CO₂H group.

By “cyano” is meant a —CN group.

By “cycloalkene” is meant an organic ring moiety containing at least one double bond. In one instance, a cycloalkene is X—R, in which R is optionally substituted cycloalkenyl, as described herein, and X is H, halo, alkyl, alkoxy, or hydroxyl.

By “cycloalkenyl” is meant a non-aromatic carbon-based ring composed of three to ten carbon atoms and containing at least one double bound, i.e., C═C. Examples of cycloalkenyl groups include, but are not limited to, cyclopropenyl, cyclobutenyl, cyclopentenyl, cyclopentadienyl, cyclohexenyl, cyclohexadienyl, and the like.

By “cycloalkyl” is meant a monovalent saturated or unsaturated non-aromatic cyclic hydrocarbon group of from three to ten carbons (e.g., C₃₋₈ or C₃₋₁₀), unless otherwise specified, and is exemplified by cyclopropyl, cyclobutyl, cyclopentyl, cyclohexyl, cycloheptyl, bicyclo[2.2.1.]heptyl, and the like. The term cycloalkyl also includes “cycloalkenyl,” which is defined as a non-aromatic carbon-based ring composed of three to ten carbon atoms and containing at least one double bound, i.e., C═C. Examples of cycloalkenyl groups include, but are not limited to, cyclopropenyl, cyclobutenyl, cyclopentenyl, cyclopentadienyl, cyclohexenyl, cyclohexadienyl, and the like. The cycloalkyl group can also be substituted or unsubstituted. For example, the cycloalkyl group can be substituted with one or more groups including those described herein for alkyl.

By “cycloheteroalkene” is meant an organic ring moiety containing at least one double bond and containing at least one heteroatom (e.g., nitrogen, oxygen, phosphorous, sulfur, selenium, or halo). In one instance, a cycloheteroalkene is X—R, in which R is optionally substituted cycloheteroalkenyl, as described herein, and X is H, halo, alkyl, alkoxy, or hydroxyl.

By “cycloheteroalkenyl” is meant a type of cycloalkenyl group, as defined herein, containing one, two, three, or four non-carbon heteroatoms (e.g., independently selected from the group consisting of nitrogen, oxygen, phosphorous, sulfur, selenium, or halo).

By “cycloheteroalkyl” is meant a type of cycloalkyl group, as defined herein, containing one, two, three, or four non-carbon heteroatoms (e.g., independently selected from the group consisting of nitrogen, oxygen, phosphorous, sulfur, selenium, or halo).

By “halo” is meant F, Cl, Br, or I.

By “haloalkyl” is meant an alkyl group, as defined herein, substituted with one or more halo.

By “heteroalkene” is meant an organic moiety containing at least one double bond and containing at least one heteroatom (e.g., nitrogen, oxygen, phosphorous, sulfur, selenium, or halo). In one instance, a heteroalkene is X—R, in which R is optionally substituted heteroalkenyl, as described herein, and X is H, halo, alkyl, alkoxy, or hydroxyl.

By “heteroalkenyl” is meant an alkenyl group, as defined herein, containing one, two, three, or four non-carbon heteroatoms (e.g., independently selected from the group consisting of nitrogen, oxygen, phosphorous, sulfur, selenium, or halo).

By “heteroalkyl” is meant an alkyl group, as defined herein, containing one, two, three, or four non-carbon heteroatoms (e.g., independently selected from the group consisting of nitrogen, oxygen, phosphorous, sulfur, selenium, or halo).

By “heteroalkynyl” is meant an alkynyl group, as defined herein, containing one, two, three, or four non-carbon heteroatoms (e.g., independently selected from the group consisting of nitrogen, oxygen, phosphorous, sulfur, selenium, or halo).

By “heterocycle” is meant a compound having one or more heterocyclyl moieties. Non-limiting heterocycles include optionally substituted imidazole, optionally substituted triazole, optionally substituted tetrazole, optionally substituted pyrazole, optionally substituted imidazoline, optionally substituted pyrazoline, optionally substituted imidazolidine, optionally substituted pyrazolidine, optionally substituted pyrrole, optionally substituted pyrroline, optionally substituted pyrrolidine, optionally substituted tetrahydrofuran, optionally substituted furan, optionally substituted thiophene, optionally substituted oxazole, optionally substituted isoxazole, optionally substituted isothiazole, optionally substituted thiazole, optionally substituted oxathiolane, optionally substituted oxadiazole, optionally substituted thiadiazole, optionally substituted sulfolane, optionally substituted succinimide, optionally substituted thiazolidinedione, optionally substituted oxazolidone, optionally substituted hydantoin, optionally substituted pyridine, optionally substituted piperidine, optionally substituted pyridazine, optionally substituted piperazine, optionally substituted pyrimidine, optionally substituted pyrazine, optionally substituted triazine, optionally substituted pyran, optionally substituted pyrylium, optionally substituted tetrahydropyran, optionally substituted dioxine, optionally substituted dioxane, optionally substituted dithiane, optionally substituted trithiane, optionally substituted thiopyran, optionally substituted thiane, optionally substituted oxazine, optionally substituted morpholine, optionally substituted thiazine, optionally substituted thiomorpholine, optionally substituted cytosine, optionally substituted thymine, optionally substituted uracil, optionally substituted thiomorpholine dioxide, optionally substituted indene, optionally substituted indoline, optionally substituted indole, optionally substituted isoindole, optionally substituted indolizine, optionally substituted indazole, optionally substituted benzimidazole, optionally substituted azaindole, optionally substituted azaindazole, optionally substituted pyrazolopyrimidine, optionally substituted purine, optionally substituted benzofuran, optionally substituted isobenzofuran, optionally substituted benzothiophene, optionally substituted benzisoxazole, optionally substituted anthranil, optionally substituted benzisothiazole, optionally substituted benzoxazole, optionally substituted benzthiazole, optionally substituted benzothiadiazole, optionally substituted adenine, optionally substituted guanine, optionally substituted tetrahydroquinoline, optionally substituted dihydroquinoline, optionally substituted dihydroisoquinoline, optionally substituted quinoline, optionally substituted isoquinoline, optionally substituted quinolizine, optionally substituted quinoxaline, optionally substituted phthalazine, optionally substituted quinazoline, optionally substituted cinnoline, optionally substituted naphthyridine, optionally substituted pyridopyrimidine, optionally substituted pyridopyrazine, optionally substituted pteridine, optionally substituted chromene, optionally substituted isochromene, optionally substituted chromenone, optionally substituted benzoxazine, optionally substituted quinolinone, optionally substituted isoquinolinone, optionally substituted carbazole, optionally substituted dibenzofuran, optionally substituted acridine, optionally substituted phenazine, optionally substituted phenoxazine, optionally substituted phenothiazine, optionally substituted phenoxathiine, optionally substituted quinuclidine, optionally substituted azaadamantane, optionally substituted dihydroazepine, optionally substituted azepine, optionally substituted diazepine, optionally substituted oxepane, optionally substituted thiepine, optionally substituted thiazepine, optionally substituted azocane, optionally substituted azocine, optionally substituted thiocane, optionally substituted azonane, optionally substituted azecine, etc. Optional substitutions include any described herein for aryl. Heterocycles can also include cations and/or salts of any of these.

By “heterocyclyl” is meant a 3-, 4-, 5-, 6- or 7-membered ring (e.g., a 5-, 6- or 7-membered ring), unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benzisothiazolyl, benzisoxazolyl, benzodiazepinyl, benzodiazocinyl, benzodihydrofuryl, benzodioxepinyl, benzodioxinyl, benzodioxanyl, benzodioxocinyl, benzodioxolyl, benzodithiepinyl, benzodithiinyl, benzodioxocinyl, benzofuranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotriazinonyl, benzotriazinyl, benzotriazolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl benzylsultimyl, bipyrazinyl, bipyridinyl, carbazolyl (e.g., 4H-carbazolyl), carbolinyl (e.g., β-carbolinyl), chromanonyl, chromanyl, chromenyl, cinnolinyl, coumarinyl, cytdinyl, cytosinyl, decahydroisoquinolinyl, decahydroquinolinyl, diazabicyclooctyl, diazetyl, diaziridinethionyl, diaziridinonyl, diaziridinyl, diazirinyl, dibenzisoquinolinyl, dibenzoacridinyl, dibenzocarbazolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, dioxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., 1H-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothioxolyl, naphthotriazolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiofuranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotriazolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, and the like, as well as modified forms thereof (e.g., including one or more oxo and/or amino) and salts thereof. The heterocyclyl group can be substituted or unsubstituted. For example, the heterocyclyl group can be substituted with one or more substitution groups, as described herein for aryl.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like.

By “imine” is meant an organic moiety having a —C═N— group. In one instance, an imine is R₂C═N—R, in which each R is, independently, H, optionally substituted alkyl, or optionally substituted aryl.

By “nitro” is meant an —NO₂ group.

By “oxo” is meant an ═O group.

By “silyl” is meant a moiety including a —SiR₃ group, in which R is optionally substituted alkyl or optionally substituted aryl. In one instance, the silyl group is a trialkylsilyl group of —SiR₃, where each R is, independently, optionally substituted alkyl. In another instance, the silyl group is a trialkylsilyloxy group of —OSiR₃, where each R is, independently, optionally substituted alkyl. Non-limiting silyl groups include trimethylsilyl, t-butyldimethylsilyl, t-butyldiphenylsilyl, trimethylsilyloxy, t-butyldimethylsilyloxy, or t-butyldiphenylsilyloxy.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S M et al., “Pharmaceutical salts,” J. Pharm. Sci. 1977 January; 66(1):1-19; and in “Handbook of Pharmaceutical Salts: Properties, Selection, and Use,” Wiley-VCH, April 2011 (2nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amine cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

### BRIEF DESCRIPTION OF DRAWINGS

FIG. 1 is a functional block diagram of an example of a substrate processing system including multiple substrate processing tools and a storage buffer according to the present disclosure.

FIG. 2 is a flow diagram showing certain operations in an example of a method for protection of an environmentally sensitive surface of a substrate.

FIG. 3 is a flow diagram showing certain operations in another example of a method for protection of an environmentally sensitive surface of a substrate.

FIG. 4 is a schematic showing an example of a substrate including a surface to be protected.

FIG. 5 is a flow diagram showing certain operations in an example of a method for bracing HAR structures using a film of small molecules.

FIG. 6 is a flow diagram showing certain operations in another example of a method for bracing HAR structures using a film of small molecules.

### DETAILED DESCRIPTION

Provided are small molecule films for surface protection and queue-time management and related methods. Also provided herein small molecule films for sacrificial bracing of high aspect ratio (HAR) structures and related methods.

As used herein, the term small molecule refers to molecules having a size of 1000 daltons (grams/mole) or less or dimerized versions of these molecules. In particular embodiments, the small molecule can have a size of 500 daltons or less or be dimerized versions of these molecules.

Substrate surfaces may be exposed to ambient conditions during semiconductor fabrication. Many of the substrate surfaces are sensitive to modification due to ambient or environmental exposure. The surface changes that occur can adversely impact a subsequent process and/or degrade device performance. These exposure phenomena may be referred to herein as queue time effects.

A sacrificial protection layer including a film of small molecules may be applied after processing and prior to exposure to ambient conditions during transfer or storage. In some examples, the substrates may be exposed to ambient conditions during transfer to and/or storage in a storage buffer or other location. In other examples, the substrates may be exposed to ambient conditions during transfer from one substrate processing chamber or tool to another substrate processing chamber or tool.

After storage and/or transfer and prior to additional substrate processing, the sacrificial protective layer is removed by sublimation and/or, with a short period as a liquid, evaporation. In some examples, removal of the sacrificial protective layer is performed in a substrate processing tool and then other processes are performed on the substrate in the same substrate processing tool without exposure to ambient conditions. In some examples, a single substrate has the sacrificial protection layer applied and removed a plurality of times during substrate processing.

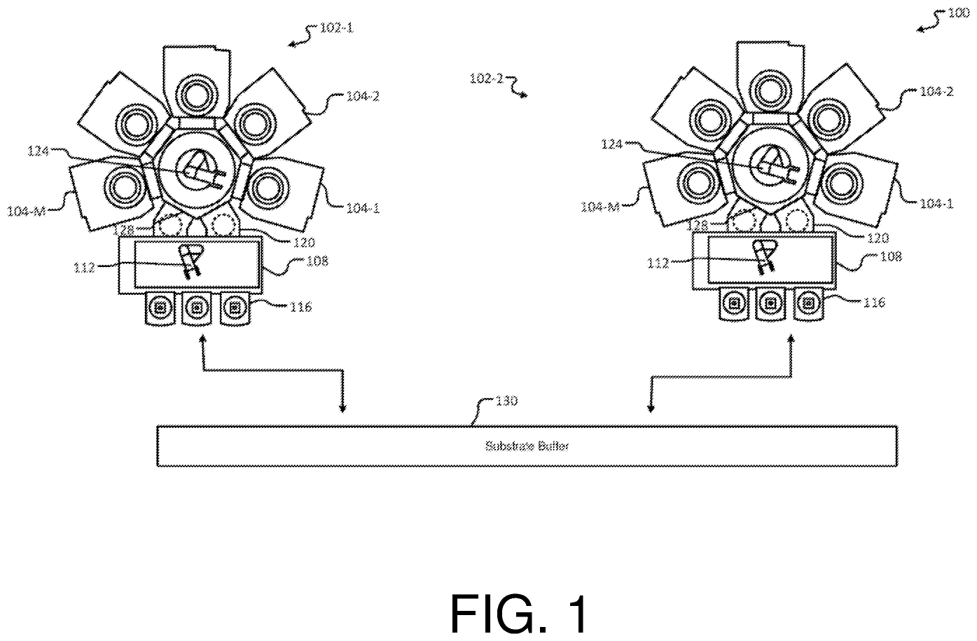

Referring now to FIG. 1, a substrate processing system 100 includes one or more substrate processing tools 102 (substrate processing tools 102-1 and 102-2 are shown for illustration purposes) and substrate buffer 130 or other substrate storage. Each of the substrate processing tools 102-1 and 102-2 includes a plurality of processing chambers 104-1, 104-2, . . . and 104-M (collectively processing chambers 104) (where M is an integer greater than one). For example only, each of the processing chambers 104 may be configured to perform a substrate treatment. In some examples, the substrates may be loaded into one of the processing chambers 104, processed, and then moved to one or more other ones of the processing chambers 104 and/or removed from the substrate processing tool 100 (e.g., if all perform the same treatment).

Substrates to be processed are loaded into the substrate processing tools 102-1 and 102-2 via ports of a loading station of an atmosphere-to-vacuum (ATV) transfer module 108. In some examples, the ATV transfer module 108 includes an equipment front end module (EFEM). The substrates are then transferred into one or more of the processing chambers 104. For example, a transfer robot 112 is arranged to transfer substrates from loading stations 116 to load locks 120. A vacuum transfer robot 124 of a vacuum transfer module 128 is arranged to transfer substrates from the load locks 120 to the various processing chambers 104.

After processing in one or more of the substrate processing tools 102-1 and 102-2, the substrates may be transported outside of a vacuum environment. For example, the substrates may be moved to a location for storage (such as the substrate buffer 130). In other examples, the substrates may be moved directly from the substrate processing tool to another substrate processing tool for further processing or from the storage buffer 130 to another substrate processing tool for further processing.

Exposure of the substrate to ambient conditions may cause defects or otherwise adversely impact downstream processing. Systems and methods according to the present disclosure are used to add the sacrificial protective layer to the substrate prior to exposure to ambient conditions. In some examples, the sacrificial protective layer is applied in the substrate processing tool prior to transferring the substrate to the substrate buffer for storage or to another substrate processing tool. In other examples, the sacrificial protective layer is applied in another processing chamber (not associated with the substrate processing tool).

Prior to performing another treatment on the substrate, the sacrificial protective layer is removed. For example, the substrate may be transferred to the substrate processing tool 102-2 after a period of storage in the storage buffer 130 or after processing in the substrate processing tool 102-1. The sacrificial protective layer may be removed in one of the processing chambers in the substrate processing tool 102-2, another processing chamber (not associated with the substrate processing tool 102-2). In some embodiments, the sacrificial protective layer is removed in a load lock 120.

In some examples, the sacrificial protective layer is applied by a processing chamber in the same substrate processing tool (that performed substrate treatment) prior to exposure to ambient conditions. Since the substrate processing tool operates at vacuum, exposure of the substrate to ambient conditions is prevented.

In some examples, the sacrificial layer is deposited after a wet clean process. In this case, oxides and residues may be removed by the wet clean process and the sacrificial layer is deposited in sequence prior to drying the wafer. In some examples, this process is not done under vacuum and is done without any exposure of the dry pristine surface to the ambient.

In other examples, the substrate is transported from the substrate processing tool to another processing chamber located outside of the substrate processing tool that adds the sacrificial protective layer. Using this approach limits or reduces the period of exposure of the substrate to ambient conditions. Exposure is limited to a brief period of transport from the substrate processing tool to the processing chamber where the sacrificial protective layer is applied. Storage of the substrate may be performed for longer periods without additional exposure to ambient conditions.

Subsequently, the sacrificial protective layer may be removed prior to further processing. In some examples, the sacrificial protective layer is removed in another substrate processing tool under vacuum conditions prior to substrate treatment in processing chambers of the same substrate processing tool. In other examples, the substrate is transported to a processing chamber that removes the sacrificial protective layer and then to the substrate processing tool for further processing. This approach also limits exposure to ambient conditions between the processing chamber and the substrate processing tool or other environment.

In one example, the sacrificial protective layer is formed immediately after etch, deposition, or other process by exposing the substrate to a small molecule vapor that condenses on the surface to form a film. This can be performed directly inside the tool in which the etch or deposition occurred (e.g., substrate processing tool 102-1) and may occur in the same processing chamber in which the etch or deposition occurred. The substrate is then taken to the next tool for processing (e.g., substrate processing tool 102-2). Once the substrate is again no longer exposed to ambient conditions (for example by bringing the substrate under vacuum or an atmosphere purged with an inert gas) vacuum and stimuli are applied to induce the film to degrade and be removed from the substrate. This may take place for example inside of the load lock (e.g., load lock 120) or inside of the next processing chamber (e.g., processing chamber 104-1),

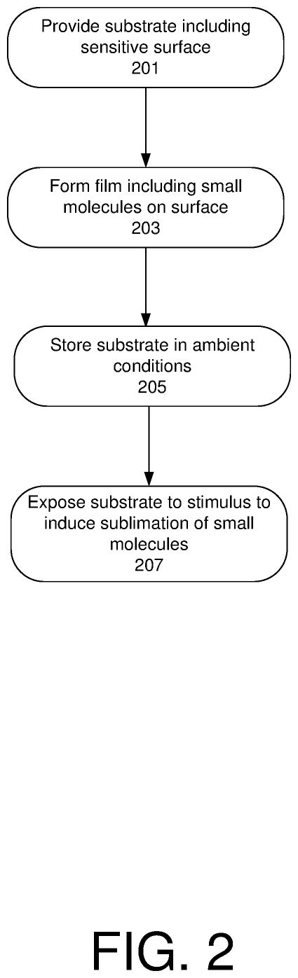

FIG. 2 shows an example of a method for protection of an environmentally sensitive surface of a substrate. At operation 201, a substrate including a sensitive surface is provided. The surface may be a planar surface or include one or more pillars, holes, and trenches, including HAR structures. Examples of substrate surfaces that can be sensitive to environmental queue time effects include silicon, silicon germanium, and germanium structures such as fins and nanowires, metal surfaces including but not limited to tungsten or molybdenum, and/or other structures and materials.

A film including small molecules is then formed on the substrate in an operation 203. In some embodiments, this may involve exposing the surface to a vapor including the small molecules such that they condense on the surface to form the film. In some embodiments, this may involve spin-coating a solution including the small molecules in an appropriate solvent, and then removing the solvent. Non-limiting methodologies of forming a film include vapor-based deposition, such as chemical vapor deposition; and solvent-based deposition, such as spin-coating, drop-casting, or solvent-casting. As described further below, in some embodiments, after operation 203, a stimulus may be applied to convert the molecule to a less volatile form for stability.

The film formed in operation 203 may be the sacrificial protective layer described above with reference to FIG. 1. The substrate can then be stored in ambient conditions in an operation 205. When ready for further processing, the substrate is exposed to a stimulus, such as heat and/or light, that induces sublimation or evaporation in an operation 207. As described further below, in some embodiments, prior to or as part of operation 207, a stimulus may be applied to convert the molecule to a more volatile form for easy removal.

The small molecules may have relatively low vapor pressure at room temperature; in some embodiments, it less than about 1×10⁻⁴ atm or less than about 76 mTorr. The small molecules are solid at atmospheric pressure and room temperature (about 20° C.-25° C.). The small molecules are further characterized by having a vapor pressure of at least 10 Torr at a temperature higher than 20° C. below about 400° C. Examples of such small molecules include fused aromatic rings such as naphthalene and anthracene.

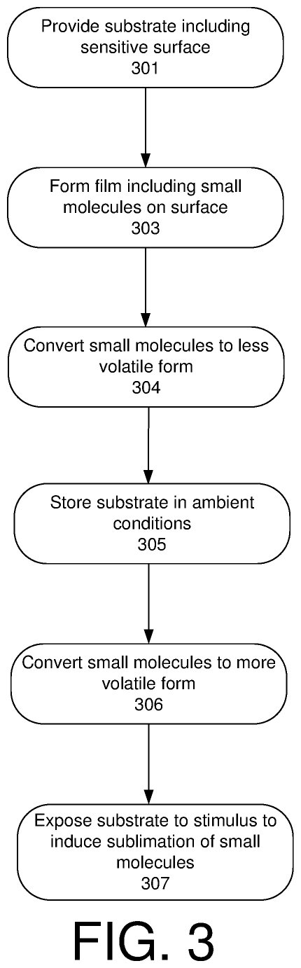

The film of small molecules may have a non-negligible vapor pressure once on the substrate, potentially contaminating the loading stations or other storage units, or contaminating the wafer backside during queue time. Thus, a chemical or physical switch may be incorporated into the molecule such that once on the substrate, it becomes significantly less volatile than in its initial form and is locked into place. FIG. 3 shows another example of a method for protection of an environmentally sensitive surface of a substrate. Operations 301 and 303 are performed as described above with respect to operations 201 and 203 of FIG. 2. Then, in an operation 304, the small molecules are converted to a less volatile form. In some other embodiments, the film may be formed with the less volatile form such that operation 304 is not performed, or not performed while the molecules are on the substrate surface. The substrate in then stored in ambient conditions in an operation 305. Once ready for the next processing operation, the molecules are converted to the more volatile form in an operation 306. The substrate is then exposed to a stimulus to induce sublimation or evaporation of the small molecules in an operation 307. Operation 306 may be part of or overlap with operation 307.

Operations 304 and 306 involve exposure to appropriate stimulus including radiation, heat, or exposure to a particular compound under appropriate conditions. For example, in some embodiments, operations 304 and 306 involves exposing the film to light at specific wavelength. In some embodiments, operation 304 involves a mixture of chemicals supplied under specific conditions to form the less volatile form. Examples of reversible chemical reactions that may be performed in operation 304 include photoisomerization of a molecule such as stilbene from trans to cis, photodimerization, and a combination reaction such as a Diels-Alder reaction.

In a specific example, operation 304 involves the dimerization of anthracene, which requires UV light to go forward (e.g., UV light above 300 nm, which can promote photo-cycloaddition to promote dimerization). It is reversible in operation 306 with the trigger of heat or additional UV light of a higher energy, such as UV light below 300 nm (e.g., which can reverse the photo-cycloaddition reaction, thus producing monomers).

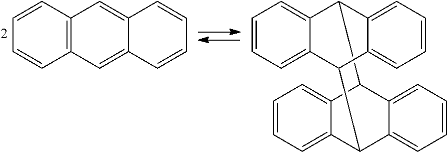

In some embodiments, operation 304 involves a Diels-Alder reaction:

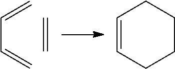

For example, cyclopentadiene reacts spontaneously at room temperature to yield dicyclopentadiene, and reverts back to cyclopentadiene at temperatures above approximately 125° C. Addition of heat can thermally reverse the cycloaddition reaction, thereby producing the initial reactants. As discussed above, in some embodiments, operation 304 may be omitted with operation 306 performed to form cyclopentadiene.

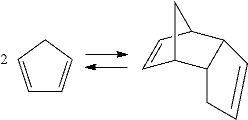 [SMILES: C1=CCC=C1 ; C1=CC2C3C=CC(C3)C2C1]

Other photodimerization, photopolymerization, photoisomerization, and Diels-Alder reactions can be employed with small molecules useful for conducting such reactions, as described herein.

Photodimerization and photopolymerization can include, for instance, optionally substituted anthracene or optionally substituted naphthalene. Optional substitutions for such compounds can include alkyl, alkenyl, alkynyl, aryl, heterocyclyl, cyano, nitro, amino, aminoalkyl, azido, azidoalkyl, hydroxyl, hydroxyalkyl, halo, haloalkyl, carboxyl (—CO₂H), carboxyalkyl, carboxyaldehyde (—C(O)H), alkoxy, aryloxy, alkanoyl (e.g., —C(O)—R, in which R is alkyl), aryloyl (e.g., —C(O)—R, in which R is aryl), alkanoyloxy (e.g., —O—C(O)—R, in which R is alkyl), aryloyloxy (e.g., —O—C(O)—R, in which R is aryl), alkoxycarbonyl (e.g., —C(O)—OR, in which R is alkyl), aryloxycarbonyl (e.g., —C(O)—OR, in which R is aryl), and/or oxo.

In one embodiment, the small molecule is a compound including formula (I):

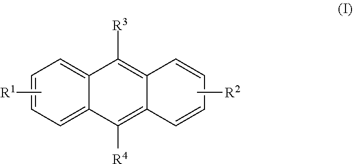

or a salt thereof, in which each of R¹, R², R³, and R⁴ is, independently, H, optionally substituted alkyl, optionally substituted alkenyl, optionally substituted alkynyl, optionally substituted aryl, optionally substituted heterocyclyl, cyano, nitro, optionally substituted amino, azido, hydroxyl, halo, carboxyl, carboxyaldehyde, optionally substituted alkoxy, optionally substituted aryloxy, optionally substituted alkanoyl, and/or optionally substituted aryloyl. In some instances, the small molecule can undergo photodimerization to provide a dimer including formula (Ia):

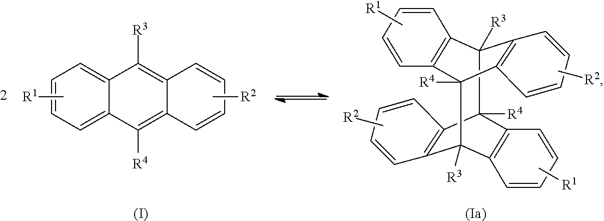

in which each of R¹, R², R³, and R⁴ can be any described herein for formula (I). The photodimerization reaction can also result in a dimer that is a structural isomer of formula (Ia), such as a positional isomer in which the position of substituents R¹, R², R³, and R⁴ can differ based on the alignment of the monomer (formula (I)) during photodimerization.

In another embodiment, the small molecule is a compound including formula (II):

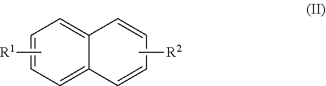

or a salt thereof, in which each of R¹ and R² is, independently, H, optionally substituted alkyl, optionally substituted alkenyl, optionally substituted alkynyl, optionally substituted aryl, optionally substituted heterocyclyl, cyano, nitro, optionally substituted amino, azido, hydroxyl, halo, carboxyl, carboxyaldehyde, optionally substituted alkoxy, optionally substituted aryloxy, optionally substituted alkanoyl, and/or optionally substituted aryloyl. In some instances, the small molecule can undergo photodimerization to provide a dimer including formula (IIa):

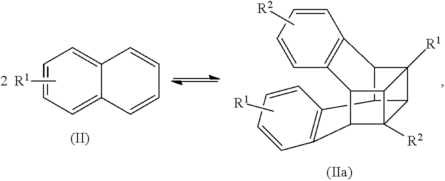

in which each of R¹ and R² can be any described herein for formula (II). The photodimerization reaction can also result in a dimer that is a structural isomer of formula (IIa), such as a positional isomer in which the position of substituents R¹ and R² can differ based on the alignment of the monomer (formula (II)) during photodimerization.

Photoisomerization, as well as photodimerization and photopolymerization reactions, can be employed with stilbene or derivatives thereof. Optional substitutions for such compounds can include alkyl, alkenyl, alkynyl, aryl, heterocyclyl, cyano, nitro, amino, aminoalkyl, azido, azidoalkyl, hydroxyl, hydroxyalkyl, halo, haloalkyl, carboxyl, carboxyalkyl, carboxyaldehyde, alkoxy, aryloxy, alkanoyl, aryloyl, alkanoyloxy, aryloyloxy, alkoxycarbonyl, aryloxycarbonyl, and/or oxo.

In one embodiment, the small molecule is a compound including formula (III):

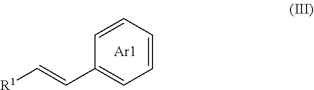

or a salt thereof, in which R¹ is H, optionally substituted alkyl, optionally substituted alkenyl, optionally substituted alkynyl, optionally substituted aryl, optionally substituted heterocyclyl, cyano, nitro, azido, hydroxyl, halo, carboxyl, carboxyaldehyde, optionally substituted alkoxy, optionally substituted aryloxy, optionally substituted alkanoyl, optionally substituted aryloyl, optionally substituted alkoxycarbonyl, or optionally substituted aryloxycarbonyl; and Ar1 is optionally substituted with one or more of the following: optionally substituted alkyl, optionally substituted alkenyl, optionally substituted aryl, optionally substituted heterocyclyl, cyano, nitro, amino, optionally substituted aminoalkyl, azido, optionally substituted azidoalkyl, hydroxyl, optionally substituted hydroxyalkyl, halo, optionally substituted haloalkyl, carboxyl, optionally substituted carboxyalkyl, carboxyaldehyde, optionally substituted alkoxy, optionally substituted aryloxy, optionally substituted alkanoyl, optionally substituted aryloyl, optionally substituted alkanoyloxy, optionally substituted aryloyloxy, optionally substituted alkoxycarbonyl, and/or optionally substituted aryloxycarbonyl.

In some instances, the small molecule can undergo photodimerization to provide a dimer including formula (IIIa):

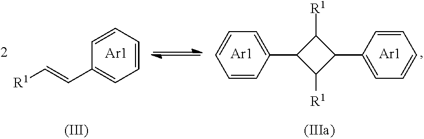

in which each of R¹ and Ar1, independently, can be any described herein for formula (III). The photodimerization reaction can also result in a dimer that is a structural isomer of formula (IIIa), such as a positional isomer in which the position of substituents R¹ and Ar1 can differ based on the alignment of the monomer (formula (III)) during photodimerization.

In another instance, the small molecule is a compound including formula (IV):

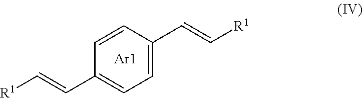

or a salt thereof, in which each R¹ is, independently, H, optionally substituted alkyl, optionally substituted alkenyl, optionally substituted alkynyl, optionally substituted aryl, optionally substituted heterocyclyl, cyano, nitro, azido, hydroxyl, halo, carboxyl, carboxyaldehyde, optionally substituted alkoxy, optionally substituted aryloxy, optionally substituted alkanoyl, optionally substituted aryloyl, optionally substituted alkoxycarbonyl, or optionally substituted aryloxycarbonyl; and Ar1 is optionally substituted with one or more of the following: optionally substituted alkyl, optionally substituted alkenyl, optionally substituted aryl, optionally substituted heterocyclyl, cyano, nitro, amino, optionally substituted aminoalkyl, azido, optionally substituted azidoalkyl, hydroxyl, optionally substituted hydroxyalkyl, halo, optionally substituted haloalkyl, carboxyl, optionally substituted carboxyalkyl, carboxyaldehyde, optionally substituted alkoxy, optionally substituted aryloxy, optionally substituted alkanoyl, optionally substituted aryloyl, optionally substituted alkanoyloxy, optionally substituted aryloyloxy, optionally substituted alkoxycarbonyl, and/or optionally substituted aryloxycarbonyl.

In some instances, the small molecule can undergo photopolymerization to provide a polymer including formula (IVa):

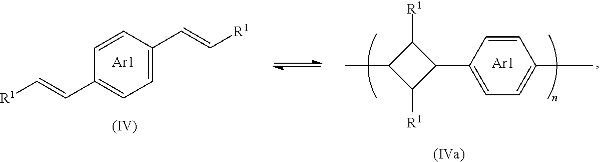

in which each of R¹ and Ar1, independently, can be any described herein for formula (IV) and in which n is from 1 to 10,000. The photopolymerization reaction can also result in a polymer that is a structural isomer of formula (IVa), such as a positional isomer in which the position of substituents R¹ and Ar1 can differ based on the alignment of the monomer (formula (IV)) during photopolymerization.

In yet another instance, the small molecule is a compound including formula (V):

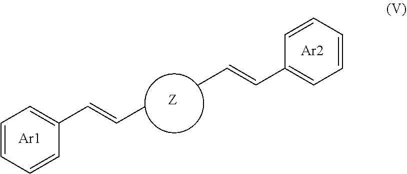

or a salt thereof, in which Z is an optionally substituted aryl, optionally substituted heteroaryl, or optionally substituted heterocyclyl; and each of Ar1 and Ar2 is, independently, optionally substituted with one or more of the following: optionally substituted alkyl, optionally substituted alkenyl, optionally substituted aryl, optionally substituted heterocyclyl, cyano, nitro, amino, optionally substituted aminoalkyl, azido, optionally substituted azidoalkyl, hydroxyl, optionally substituted hydroxyalkyl, halo, optionally substituted haloalkyl, carboxyl, optionally substituted carboxyalkyl, carboxyaldehyde, optionally substituted alkoxy, optionally substituted aryloxy, optionally substituted alkanoyl, optionally substituted aryloyl, optionally substituted alkanoyloxy, optionally substituted aryloyloxy, optionally substituted alkoxycarbonyl, and/or optionally substituted aryloxycarbonyl.

In some instances, the small molecule can undergo photopolymerization to provide a polymer including formula (Va):

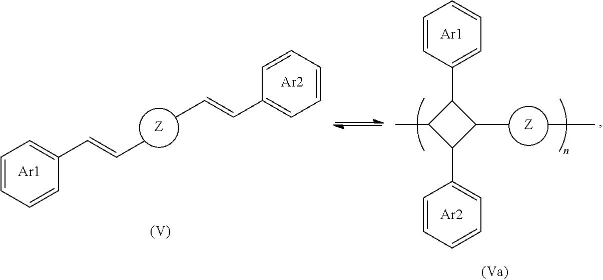

in which each of Z, Ar1, and Ar2, independently, can be any described herein for formula (V) and in which n is from 1 to 10,000. The photopolymerization reaction can also result in a polymer that is a structural isomer of formula (Va), such as a positional isomer in which the position of substituents Z, Ar1, and Ar2 can differ based on the alignment of the monomers (formula (V)) during photopolymerization.

Diels-Alder reactions may be performed by employing a diene (or a diyne) and a dienophile (or a diynophile) to provide a cyclic derivative. Non-limiting dienes include a cyclic or acyclic compound having two or more double bonds, such as those having a 4π electron system, including an optionally substituted 1,3-unsaturated compound (e.g., optionally substituted 1,3-butadiene, optionally substituted cyclopentadiene, optionally substituted cyclohexadiene, optionally substituted furan, optionally substituted thiofuran, or optionally substituted imine) or an optionally substituted benzene. Non-limiting diynes include a cyclic or acyclic compound having two or more triple bonds, such as an optionally substituted 1,3-butadiyne. Non-limiting dienophiles, heterodienophiles, and diynophiles having a 2π electron system include an optionally substituted alkene, optionally substituted alkyne, optionally substituted ketone, optionally substituted aldehyde, optionally substituted heteroalkene, optionally substituted imine, optionally substituted benzene, optionally substituted cycloalkene, and optionally substituted cycloheteroalkene.

The cyclic derivative can include, e.g., an optionally substituted cycloalkene (e.g., optionally substituted cyclohexene or optionally substituted 1,4-cyclohexadiene), optionally substituted dihydropyran (e.g., optionally substituted 3,6-dihydro-2H-pyran), optionally substituted tetrahydropyridine (e.g., optionally substituted 1,2,3,6-tetrahydropyridine), optionally substituted benzene, optionally substituted dihydronaphthalene, optionally substituted norbornene, optionally substituted heteronorbornene, optionally substituted benzonorbornene, optionally substituted heterocycle, optionally substituted carbocycle, or optionally substituted dicyclopentadiene.

The diene, diyne, dienophile, diynophile, and cyclic derivative can include one or more optional substitutions, such as any described herein for alkyl and aryl. In other embodiments, optional substitutions for such compounds include alkyl, alkenyl, alkynyl, aryl, heterocyclyl, cyano, nitro, amino, aminoalkyl, azido, azidoalkyl, hydroxyl, hydroxyalkyl, halo, haloalkyl, carboxyl, carboxyalkyl, carboxyaldehyde, alkoxy, aryloxy, alkanoyl, aryloyl, alkanoyloxy, aryloyloxy, alkoxycarbonyl, aryloxycarbonyl, oxo, trialkylsilyl (e.g., —SiR₃, in which R is alkyl as defined herein), or trialkylsilyloxy (e.g., —OSiR₃, in which R is alkyl as defined herein).

A non-limiting Diels-Alder reaction includes the following:

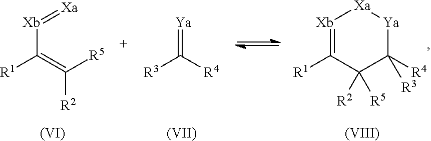

in which a first small molecule including formula (VI) is reacted with a second small molecule including formula (VII) to provide a cyclic derivative having formula (VIII).

In one embodiment, the small molecule is a compound including formula (VI):

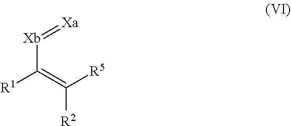

or a salt thereof, in which

Xa is ═CR^{a}R^{b}, ═NR^{a}, ═O, or ═S, in which ═ indicates a bivalent moiety;

Xb is ═CR^{a}— or ═N—, in which use of ═ with — indicates a trivalent moiety;

each of R¹, R², R⁵, R^{a}, and R^{b} is, independently, H, optionally substituted alkyl, optionally substituted alkenyl, optionally substituted alkynyl, optionally substituted aryl, optionally substituted heterocyclyl, cyano, nitro, azido, hydroxyl, halo, carboxyl, carboxyaldehyde, optionally substituted alkoxy, optionally substituted aryloxy, optionally substituted alkanoyl, optionally substituted aryloyl, optionally substituted alkoxycarbonyl, optionally substituted aryloxycarbonyl, optionally substituted trialkylsilyl, or optionally substituted trialkylsilyloxy; and

wherein Xa and R⁵ can optionally be taken together to be ═CRₐ—Xc-, in which Xc is —O—, —S—, —NR^{a}—, —C(O)O—, or optionally substituted alkylene (e.g., —CR^{a}R^{b}— or —CR^{a1}R^{b1}CR^{a2}R^{b2}—, in which R^{a}, R^{a1}, R^{a2}, R^{b}, R^{b1}, and R^{b2} are any described herein for R^{a} or R^{b}).

In particular embodiments, small molecule is a compound including formula (VIa) or (VIb):

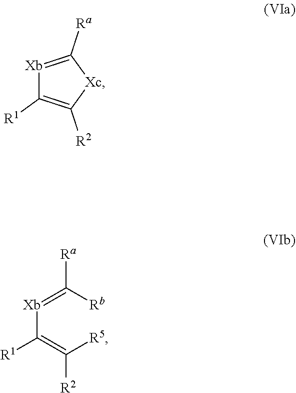

or a salt thereof, in which each of Xb, Xc, R¹, R², R⁵, R^{a}, and R^{b} can be any described herein for formula (VI).

In another embodiment, the small molecule is a compound including formula (VII):

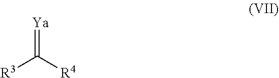

or a salt thereof, in which

Ya is ═CR^{a}R^{b}, ═NR^{a}, ═O, or ═S, in which ═ indicates a bivalent moiety;

each of R³, R⁴, R^{a}, R^{a1}, R^{a2}, R^{a3}, and R^{b} is, independently, H, optionally substituted alkyl, optionally substituted alkenyl, optionally substituted alkynyl, optionally substituted aryl, optionally substituted heterocyclyl, cyano, nitro, azido, hydroxyl, halo, carboxyl, carboxyaldehyde, optionally substituted alkoxy, optionally substituted aryloxy, optionally substituted alkanoyl, optionally substituted aryloyl, optionally substituted alkoxycarbonyl, or optionally substituted aryloxycarbonyl; and

wherein Ya and R⁴ can optionally be taken together to be ═CR^{a1}—CR^{a2}═CR^{a3}—Xc-, in which Xc is —O—, —S—, —NR^{a}—, —C(O)O—, or optionally substituted alkylene (e.g., —CR^{a}R^{b}— or —CR^{a1}R^{b1}CR^{a2}R^{b2}—, in which R^{a}, R^{a1}, R^{a2}, R^{b}, R^{b1}, and R^{b2} are any described herein for R^{a} or R^{b}).

In particular embodiments, the small molecule is a compound including one of formulas (VIIa)-(VIId):

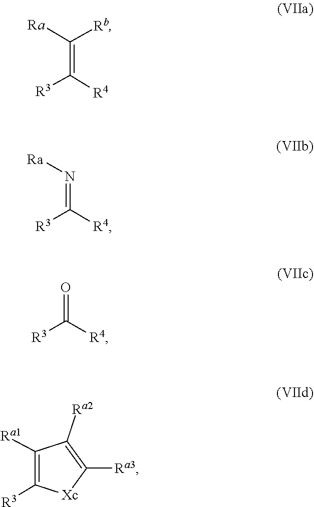

or a salt thereof, in which each of Xc, R³, R⁴, R^{a}, Rₐ₁, R^{a2}, R^{a3}, and R^{b} can be any described herein for formula (VII).

Reactions between two small molecules can provide a cyclic derivative, such as, e.g., a compound including formula (VIII):

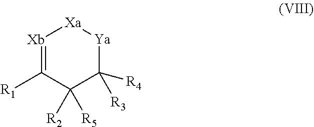

or a salt thereof, in which

each of Xa and Ya is, independently, ═CR^{a}R^{b}, ═NR^{a}, ═O, or ═S, in which ═ indicates a bivalent moiety;

Xb is ═CR^{a}— or ═N—, in which use of ═ with — indicates a trivalent moiety;

each of R¹, R², R³, R⁴, R⁵, R^{a}, R^{a1}, Rₐ₂, R^{a3}, and R^{b} is, independently, H, optionally substituted alkyl, optionally substituted alkenyl, optionally substituted alkynyl, optionally substituted aryl, optionally substituted heterocyclyl, cyano, nitro, azido, hydroxyl, halo, carboxyl, carboxyaldehyde, optionally substituted alkoxy, optionally substituted aryloxy, optionally substituted alkanoyl, optionally substituted aryloyl, optionally substituted alkoxycarbonyl, optionally substituted aryloxycarbonyl, optionally substituted trialkylsilyl, or optionally substituted trialkylsilyloxy; and

wherein Ya and R⁴ can optionally be taken together to be ═CR^{a1}—CR^{a2}═CR^{a3}—Xc-, and

wherein Xa and R⁵ can optionally be taken together to be ═CR^{a}—Xc-, in which Xc is —O—, —S—, —NR^{a}—, —C(O)O—, or optionally substituted alkylene (e.g., —CR^{a}R^{b}— or —CR^{a1}R^{b1}CR^{a2}R^{b2}, in which R^{a}, R^{a1}, R^{a2}, R^{b}, R^{b1}, and R^{b2} are any described herein for R^{a} or R^{b}).

In particular embodiments, the cyclic derivative is a compound including one of formulas (VIIIa)-(VIIIe):

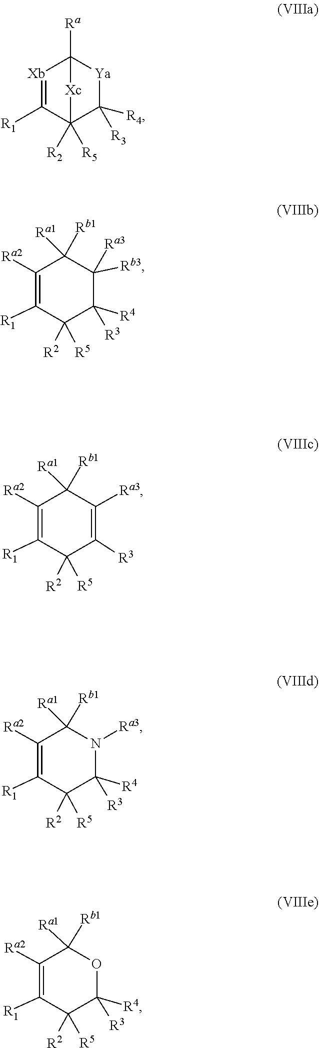

or a salt thereof, in which each of Xb, Xc, Ya, R¹, R², R³, R⁴, R⁵, R^{a}, R^{a1}, R^{a2}, R^{a3}, R^{b}, R^{b1}, and R^{b3} can be any described herein for formula (VIII). In particular instances, R^{b1} and R^{b3} are any described herein for R^{b} in formula (VIII).

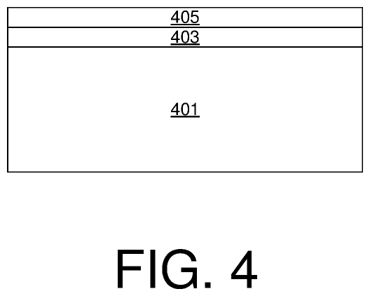

In some embodiments, the sacrificial protective layer including small molecules may be part of a multi-layer transient protective film. FIG. 4 shows an example of a substrate 401 including a surface to be protected. A multi-layer film including small molecule layer 403 and layer 405 is on the substrate surface and serves as a transient protective layer. For example, the multi-layer film may be implemented to protect surfaces as described above with respect to FIG. 2. In addition to the small molecule layer, the multi-layer film includes one or more cap layers that provide protection from unwanted oxidation, corrosion, or halogenation due to exposure to ambient conditions. In the example of FIG. 4, there is one cap layer 405, however additional cap layers of the same or different composition may be used. Examples of thicknesses may range from 2-1000 nm for a small molecule layer, and from a few nm's to several microns for the one or more cap layers. Thicknesses may depend on storage ambient and length of time, for example.

The cap layer 405 may be a high density material with little-to-no porosity or defects. It is deposited in a manner that does not degrade the small molecule material. Example deposition processes can include electron-beam evaporation, various sputtering processes, atomic layer deposition, and chemical vapor deposition. Example cap layers can include oxide films such as SiOₓ, SnOₓ, AlOₓ, TiOₓ, ZrOₓ, HfOₓ, and ZnOₓ, and nitride films such as SiNₓ wherein x is a number greater than 0. In some embodiments, the cap layer may be a polymer film.

The layer in contact with the environmentally sensitive surface generally contains the small molecules, which can be removed in a benign way with little residue left behind. To construct the film, the small molecule layer is first spin-coated or vapor deposited. Then one or more cap layers are subsequently deposited onto the small molecule layer. Vapor-phase, low temperature, non-plasma CVD techniques may be used to avoid small molecule degradation. Additionally, the cap layer may be spun cast on top of the small molecule film using a solvent that does not dissolve the small molecule layer. Multiple different types of films may be deposited multiple times in a repeated stack to optimize protection of the surface.

In some embodiments, a first cap layer may be deposited by a mild CVD process to protect the small molecule film followed by deposition by a harsher technique such as PECVD to grow faster, more robust films. The temperature of the substrate should generally be below a degradation temperature of the small molecule film throughout the entire process, or exceed it for no more than a few seconds.

Removing the one or more cap layers can involve using a plasma or solvent to degrade these layers, turning off the plasma or removing the solvent before the small molecule film itself is fully removed. The small molecule film can then be removed, leaving behind the clean surface of interest, which is protected from the harsh chemistries or conditions used to remove the cap layers.

In some embodiments, the cap layers may be peeled-off by attaching them with an adhesive to another substrate, while the first substrate remains chucked or affixed to some kind of holder. The whole assembly is then heated while being pulled apart. Since the heating may serve to degrade the small molecule material, this spot is where the two halves separate, leaving behind a clean substrate free of the protecting film, while the bulk of the protecting film remains attached by the adhesive to the second substrate.

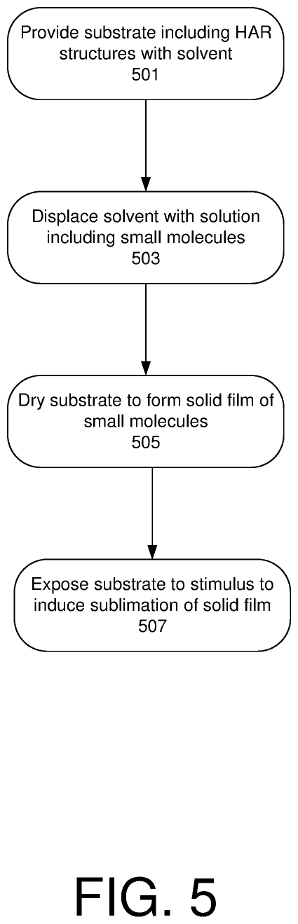

Also provided herein methods of bracing HAR structures with films of small molecules. FIG. 5 is an example of a method for bracing HAR structures using a film of small molecules. First at an operation 501, a substrate including HAR structures with a solvent is provided. HAR structures are structures having high aspect ratios (ARs), e.g., at least 8, 10, 20, 30, 40, or 80. The substrate may be provided, for example, after a wet etch or cleaning operation and have solvent associated with the prior operation. In some embodiments, the solvent in operation 501 may be a transitional solvent if the prior solvent is not chemically compatible with the small molecule solution.

Next in an operation 503, the solvent is displaced with a solution that includes small molecules. The substrate is then dried in an operation 505. The small molecules precipitate out of solution, filling the HAR structures with a solid film and/or forming the solid film within the HAR structures. The small molecules function as a mechanical brace in the HAR structures to prevent collapse of the structures due to capillary forces that are generated during solvent drying. The substrate is then exposed to a stimulus, such light or heat, that induces sublimation of the film in an operation 507.

The small molecules have relatively low vapor pressure at room temperature; in some embodiments, it less than about 1×10⁻⁴ atm or less than about 76 mTorr. The small molecules are solid at atmospheric pressure and room temperature (about 20° C.-25° C.). The small molecules are further characterized by having a vapor pressure of at least 10 Torr at a temperature above about 20° C. but below about 400° C., without having a melting point below this temperature, such that there is no transition to liquid. Examples of such small molecules include fused aromatic rings such as naphthalene and anthracene.

The solution in operation 503 includes a solvent that dissolves the small organic molecule and is chemically compatible with the substrate and the solvent in operation 501. It may be optimized for substrate wetting and displacement.

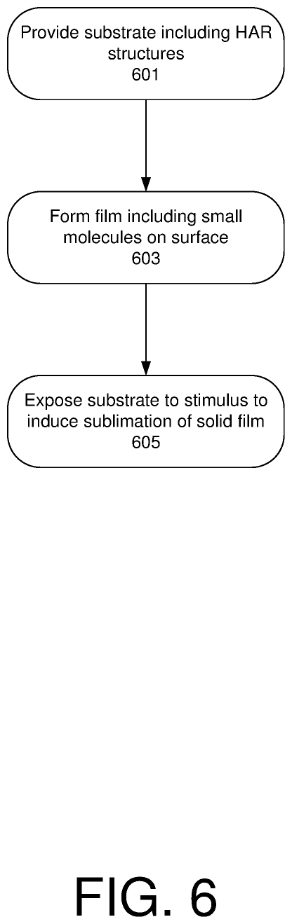

FIG. 6 is another example of a method for bracing HAR structures using a film of small molecules. First at an operation 601, a substrate including HAR structures is provided. HAR structures are structures having high aspect ratios (ARs), e.g., at least 8, 10, 20, 30, 40, or 80. In other embodiments, the substrate may be provided, for example, after a wet etch or cleaning operation and have a first solvent associated with the prior operation. If this first solvent is not chemically compatible with the small molecules, then this first solvent may be a transitional solvent that is replaced by a second solvent.

Next, in operation 603, a film including small molecules is formed on the substrate. Such forming can include exposing the surface to a vapor including the small molecules such that they condense on the surface to form the film. In other embodiments, this may involve spin-coating a solution including the small molecules in an appropriate solvent, and then removing the solvent. Non-limiting methodologies of forming a film include vapor-based deposition, such as chemical vapor deposition; and solvent-based deposition, such as spin-coating, drop-casting, or solvent-casting.

In other embodiments, forming can include displacing a solvent (e.g., the first or second solvent) of the substrate with a solution that includes small molecules. This solution can include a further solvent (e.g., a third solvent) that dissolves the small organic molecule and is chemically compatible with the substrate and the first solvent (or the second solvent) employed with the HAR structures. The further solvent (e.g., the third solvent) may be optimized for substrate wetting and displacement. The substrate can then be dried. The small molecules precipitate out of solution, filling the HAR structures with a solid film.

Whether formed by vapor-based or solution-based deposition, the small molecules of the film function as a mechanical brace in the HAR structures to prevent collapse of the structures due to capillary forces that are generated during solvent drying. The substrate is then exposed to a stimulus, such light or heat, that induces sublimation of the film in an operation 605.

The small molecules can have relatively low vapor pressure at room temperature; in some embodiments, it less than about 1×10⁻⁴ atm or less than about 76 mTorr. The small molecules are solid at atmospheric pressure and room temperature (about 20° C.-25° C.). The small molecules are further characterized by having a vapor pressure of at least 10 Torr at a temperature above about 20° C. but below about 400° C., without having a melting point below this temperature, such that there is no transition to liquid. Examples of such small molecules include fused aromatic rings such as naphthalene and anthracene.

The methods described herein may provide one or more of the following advantages for sacrificial bracing of HAR structures. In some embodiments, relatively mild conditions may be used to remove the materials, preventing damage to the sensitive underlying surface and avoiding detectable residue. Because the materials can be sublimed at lower temperatures, high temperatures that may cause charred residues can be avoided. In some embodiments, processing may take place at room temperature. Because the small molecules form solid films at room temperature in some embodiments, the process window is larger than with, for example, freeze-drying processes. In some embodiments, the small molecules are easier to produce than polymers.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
forming a film comprising small molecules on a surface of a substrate to protect the surface, thereby providing a protected surface.

2. The method of claim 1, further comprising:
storing the protected surface in ambient conditions; and
removing the small molecules from the surface of the substrate.

3. The method of claim 1, wherein said forming a film comprises a vapor comprising the small molecules or a solution comprising the small molecules.

4. The method of claim 2, wherein said removing the small molecules comprises inducing sublimation or evaporation of the small molecules.

5. The method of claim 1, further comprising, prior to said removing the small molecules, bringing the substrate into a chamber with pressure less than atmospheric pressure.

6. The method of claim 1, further comprising, prior to said removing the small molecules, converting the small molecules to a more volatile form.

7. The method of claim 1, further comprising converting the small molecules on the surface of the substrate to a less volatile form prior to said storing the protected surface in ambient conditions.

8. The method of claim 7, wherein said converting the small molecules to a less volatile form comprises photoisomerization.

9. The method of claim 7, wherein said converting the small molecules to a less volatile form comprises photodimerization.

10. The method of claim 7, wherein said converting the small molecules to a less volatile form comprises a Diels-Alder reaction.

11. The method of claim 1, wherein said converting the small molecules comprises providing a compound comprising one of formulas (Ia), (IIa), (IIIa), (IVa), (Va), and (VIII).

12. The method of claim 1, wherein the film is formed in a process chamber in which the substrate was immediately previously processed.

13. The method of claim 1, wherein at least one of the small molecules comprises a compound comprising one of formulas (I), (II), (III), (IV), (V), (VI), and (VII).

14. A method comprising:
forming a film comprising small molecules on a surface of a substrate including high aspect ratio (HAR) structures, wherein the film can fill the HAR structures or form within the HAR structures; and
exposing the substrate to a stimulus to induce sublimation of the small molecules.

15. (canceled)

16. The method of claim 14, wherein the substrate including the HAR structures further comprises a first solvent, and wherein said forming the film comprises: displacing the first solvent with a solution including small molecules and drying the substrate to form a solid film of small molecules.

17. The method of claim 14, wherein the small molecules are characterized by having a vapor pressure of less than about 76 mTorr at room temperature.

18. The method of claim 14, wherein the small molecules are solid at room temperature and atmospheric pressure.

19. The method of claim 14, wherein the small molecules have a vapor pressure of at least 10 Torr and no melting point at temperature less than about 400° C.

20. The method of claim 14, wherein the small molecules are fused aromatic rings.

21. The method of claim 20, wherein the small molecules are anthracene or naphthalene.

22. The method of claim 14, wherein at least one of the small molecules comprises a compound comprising one of formulas (I), (II), (III), (IV), (V), (VI), and (VII).

23. A processing tool comprising
one or more semiconductor substrate processing chambers connected under vacuum; and
a controller comprising instructions for forming a film comprising small molecules on a surface of a substrate to protect the surface and exposing the substrate to a stimulus to induce sublimation of the small molecules.
